(19) United States
(12) Patent Application Publication
(10) Pub. No.: US 2009/0045736 A1
(43) Pub. Date: Feb. 19, 2009

(54) ORGANIC LIGHT EMITTING DIODE DISPLAY DEVICE AND METHOD OF FABRICATING THE SAME

(76) Inventors: Sam-Il Kho, Suwon-si (KR); Byeong-Wook Yoo, Suwon-si (KR); Sun-Hee Lee, Suwon-si (KR); Sang-Bong Lee, Suwon-si (KR)

Correspondence Address: CHRISTIE, PARKER & HALE, LLP, PO BOX 7068, PASADENA, CA, 91109-7068, US

(21) Appl. No.: 12/191,978

(22) Filed: Aug. 14, 2008

(30) Foreign Application Priority Data
Aug. 16, 2007 (KR) 10-2007-0082354

(51) Int. Cl. H01L 51/52; B05D 5/12

(52) U.S. Cl. 313/504; 427/77

(57) ABSTRACT

An organic light emitting diode (OLED) display device and a method of fabricating the same are provided. The OLED display device includes: a substrate; a first electrode on the substrate; an organic layer on the first electrode, and including a white emission layer including a mixed host having a first host and a second host having a different polarity from the first host; and a second electrode on the organic layer.

### CROSS-REFERENCE OF RELATED APPLICATION

This application claims priority to and the benefit of Korean Patent Application No. 10-2007-0082354, filed Aug. 16, 2007, the entire content of which is incorporated herein by reference.

### BACKGROUND OF THE INVENTION

1. Field of the Invention

The present invention relates to an organic light emitting diode (OLED) display device having improved emission intensities of red (R), green (G) and blue (B) peaks and a method of fabricating the same, and more particularly, an OLED display device including a white emission layer having a mixed host and a method of fabricating the same.

2. Description of the Related Art

OLED display devices include a substrate, an anode on the substrate, an emission layer on the anode, and a cathode on the emission layer. In such an OLED display device, when a voltage is applied between the anode and the cathode, a hole and an electron are injected into the emission layer and then recombined to thereby generate an exciton, and thus light is emitted by the transition from an excited state to a ground state.

To realize a full-color OLED display device, respective emission layers corresponding to R, G and B colors may be formed. However, emission layers in such an OLED display device have different luminous efficiencies (cd/A). Thus, each emission layer has different brightness, which is generally proportional to a current. As a result, when the same current is applied, one layer may have relatively low brightness, and another layer may have relatively high brightness, and thus it is difficult to obtain an appropriate color balance or white balance. For example, because the luminous efficiency of the green emission layer is 3 to 6 times higher than those of the red and blue emission layers, much more current has to be applied to the red and blue emission layers in order to obtain an appropriate white balance.

To solve this problem, there is a method in which an emission layer emitting single color light, e.g., white light, is formed, along with a color filter layer for extracting light corresponding to a specific color from the emission layer, or a color conversion layer for converting the light emitted from the emission layer into light of a specific color is formed. Here, the OLED display device realizing or producing white light includes a multi-layered emission layer containing a dopant in a single host.

However, the conventional OLED display device realizing white light has a problem of low luminous efficiencies of R, G and B peaks. Also, because the multi-layered emission layer has layers with different life-span characteristics, the balance of the R, G and B peaks may be broken as time passes, and thus the OLED display device may not realize (or produce) white light for a long period of time.

### SUMMARY OF THE INVENTION

Aspects of an embodiment of the present invention are directed toward an organic light emitting diode (OLED) display device having improved luminous efficiency and life-span characteristics and a method of fabricating the same.

According to an embodiment of the present invention, an OLED display device includes: a substrate; a first electrode disposed on the substrate; an organic layer disposed on the first electrode, and including a white emission layer having a first host and a second host having a different polarity from the first host; and a second electrode disposed on the organic layer.

According to another embodiment of the present invention, a method of fabricating the OLED display device includes: preparing a substrate; forming a first electrode on the substrate; forming an organic layer including a white emission layer having a first host and a second host having a different polarity from the first host on the first electrode; and forming a second electrode on the organic layer.

### BRIEF DESCRIPTION OF THE DRAWINGS

The accompanying drawings, together with the specification, illustrate exemplary embodiments of the present invention, and, together with the description, serve to explain the principles of the present invention.

FIG. 1 is a cross-sectional schematic view of an organic light emitting diode (OLED) display device according to an exemplary embodiment of the present invention;

FIG. 2 is a graph illustrating an EL spectrum according to Example 1;

FIG. 3 is a graph illustrating an EL spectrum according to Comparative Example 1;

FIG. 4 is a graph illustrating a relationship between luminous efficiency and brightness in Example 1 and Comparative Example 1;

FIG. 5 is a graph illustrating a relationship between luminous flux efficiency and brightness in Example 1 and Comparative Example 1;

FIG. 6 is a graph illustrating a relationship between current density and driving voltage in Example 1 and Comparative Example 1;

FIG. 7 is a graph illustrating a relationship between brightness and current density in Example 1 and Comparative Example 1; and

FIG. 8 is a graph illustrating a relationship between brightness and driving voltage in Example 1 and Comparative Example 1.

### DETAILED DESCRIPTION

In the following detailed description, only certain exemplary embodiments of the present invention are shown and described, by way of illustration. As those skilled in the art would recognize, the invention may be embodied in many different forms and should not be construed as being limited to the embodiments set forth herein. Also, in the context of the present application, when an element is referred to as being “on” another element, it can be directly on the another element or be indirectly on the another element with one or more intervening elements interposed therebetween. Like reference numerals designate like elements throughout the specification.

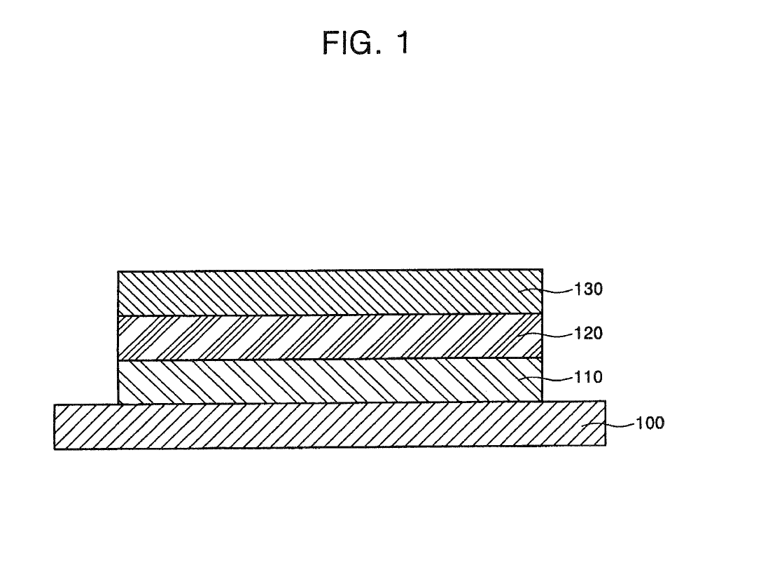

FIG. 1 is a cross-sectional schematic view of an organic light emitting diode (OLED) display device according to an exemplary embodiment of the present invention.

Referring to FIG. 1, the OLED display device includes a substrate 100, a first electrode 110, a second electrode 130, and an organic layer 120 interposed between the first and second electrodes 110 and 130.

In one embodiment, the OLED display device is a bottom-emission type, which emits light toward the substrate 100. Here, the first electrode 110 may be a transparent conductive layer formed of ITO, IZO or ITZO.

Also, if the OLED display device is a top-emission type, the first electrode 110 may have a double or triple layered structure further including a reflective layer in addition to the transparent conductive layer.

That is, in another embodiment, the OLED display device is a top-emission type for emitting light in an opposite direction away from the substrate 100, and in this case, the first electrode 110 may be formed in a double or triple layered structure in which a transparent conductive layer and a reflective layer are stacked.

The first electrode 110 according to an exemplary embodiment of the present invention is formed as a double layered structure by sequentially stacking a reflective layer (which is formed of aluminum (Al), silver (Ag) or an alloy thereof), and a transparent conductive layer (which is formed of ITO, IZO or ITZO).

The first electrode 110 according to another exemplary embodiment may be formed in a triple layered structure by stacking a first metal layer (which is formed of titanium (Ti), molybdenum (Mo), ITO or an alloy thereof), a second metal layer (which is formed of Al, Ag or an alloy thereof), and a third metal layer (which is formed of ITO, IZO or ITZO).

In an embodiment of the present invention, the OLED display device is an active-matrix type, and in this case, a circuit including a plurality of thin film transistors and capacitors may be formed between the substrate 100 and the first electrode 110.

The organic layer 120 may include a white emission layer including at least a mixed host.

The mixed host includes first and second hosts, which have different polarities from each other. When two or more different hosts are mixed, the concentration of charge may be increased in the white emission layer, thereby making an exciton area larger, and thus brightness, i.e., luminous efficiency, may be increased using a small amount of current. Also, the mixed host has a characteristic that may lower heat generated inside the OLED display device in a voltage drop, thereby enhancing device stability.

That is, a white emission layer including a single host has a smaller exciton area than that of the white emission layer including the mixed host so that fewer excitons are formed and involved in the emission, and thus emission time becomes shorter. As a result, the white emission layer including the mixed host has a longer life-span than that of the white emission layer including the single host.

The mixed host may include from about 50 to about 75% of the first host and from about 25 to about 50% of the second host.

In one exemplary embodiment of the present invention, the first host may be a hole transport material, and the second host may be an electron transport material.

The hole transport material may include an aryl amine series compound and/or a starburst amine compound, and more particularly, may include 4,4,4-tris(3-methylphenylamino)triphenylamine (m-MTDATA), 1,3,5-tris[4-(3-methylphenylamino)phenyl]benzene (m-MTDATB), and/or copper phthalocyanine (CuPc).

The electron transport material may include a metal complex having a quinoline skeleton and/or a benzoquinoline skeleton, a mixed ligand complex, an oxazole ligand, and/or a thiazole ligand. The quinoline skeleton may include Alq3, tris(4-methyl-8-quinolinolato)aluminum (Almq3) and/or bis(10-hydroxybenzo[h]-quinolinolato) beryllium (Bebq2). Further, the material including the mixed ligand complex may include bis(2-methyl-8-quinolinolate)-(4-hydroxy-biphenyl)-aluminum (BAlq). Furthermore, the material including the oxazole-based ligand may include bis[2-hydroxyphenyl]-benzooxazolate)zinc (Zn(BOX)2), and/or bis[2-(2-hyd roxyphenyl)-benzothiozolate]zinc (Zn(BTZ)2).

Also, the metal complex may further include an oxadiazole derivative, a triazole derivative and/or a phenanthroline derivative. The material including the oxadiazole derivative may include 2-(4-biphenyl)-5-(4-tert-butylphenyl)-1,3,4-oxadiazole (PBD), and/or 1,3-bis[5-(p-tert-butylphenyl)-1,3,4-oxadiazole-2-yl]benzene (OXD-7). Further, the material including the triazole derivative may include 3-(4-tert-butylphenyl)-4-phenyl-5-(4-biphenyl)-1,2,4-triazole (TAZ), and/or 3-(4-tert-butyl phenyl)-4-(4-enthylphenyl)-5-(4-biphenyl)-1,2,4-triazole (p-EtTAZ). Furthermore, the material including the phenanthroline derivative may include bathophenanthroline (BPhen), and/or bathocuproin (BCP).

The white emission layer is formed as a multi-layered structure, for example, a double or triple layered structure.

In one embodiment of the present invention, the white emission layer is a double layered-white emission layer for emitting light at different wavelengths. One layer may be an emission layer for emitting orange-red light, and the other layer may be an emission layer for emitting blue light. Also, the emission layer emitting orange-red light may be a phosphorescent emission layer, and the emission layer emitting blue light may be a fluorescent emission layer. While the phosphorescent emission layer has a superior emission characteristic to the fluorescent emission layer for emitting light in the same wavelength range, the fluorescent emission layer may have a longer life-span than the phosphorescent emission layer. Thus, the white emission layer formed by stacking the phosphorescent emission layer for emitting orange-red light with the fluorescent emission layer for emitting blue light may have excellent luminous efficiency and long life-span. Also, the double layered-white emission layer includes at least one emission layer containing the mixed host.

In another embodiment, the white emission layer is a triple-layered white emission layer that may have a stacked structure of red, green and blue emission layers, but the stacking order of the layers according to embodiments of the present invention is not thereby limited.

The red emission layer may include a dopant in the mixed or single host. The single host may include tris-(8-hydroxyquinoline) aluminum (Alq3), and/or 4,4′-N,N-dicarbazolylbiphenyl (CBP). Also, the red dopant may include 4-(dicyanomethylene)-2-t-butyl-6-(1,1,7,7-tetramethyljulolidyl-9-enyl)-4H-pyran (DCJTB), 4-(dicyanomethylene)-2-methyl-6-(4-dimethylaminostyryl)-4H-pyran (DCM), and/or platinum(II) porphyrins (PtOEP).

The green emission layer may include a green dopant in the mixed or single host. The single host may include Alq3 and/or CBP. Also, the green dopant may include 10-(2-benzothiazolyl)-2,3,6,7-tetrahydro-1,1,7,7-tetramethyl-1H,5H,11H-[1]benzopirano[6,7,8-ij]quinolizine-11-one (C545t), and/or tris[2-(2-pirydinyl)phenyl-C,N]-iridium (IrPPY).

Also, the blue emission layer may have a dopant in the mixed or single host. The single host may include 4,4-bis(2,2-diphenyl-ethene-1-yl)-biphenyl (DPVBi), TAZ, and/or CBP. Also, the blue dopant may include distyrylarylene (DSA), bis[2-(4,6-difluorophenyl)pyridinato-N,C2′]iridium picolinate (F2Irpic), tris[1-(4,6-difluorophenyl)pyrazolate-N,C2′]iridium (Ir[difppz]3), bis[2-(4,6-difluorophenyl)pyridinato-N,C2′]iridium picolinate (F2Irpic), and/or tris[1-(4,6-difluorophenyl)pyrazolate-N,C2′]iridium (Ir[dfppz]3). Moreover, the host material may include TMM-004 (available from COVION), TAZ, and/or CBP. When the blue emission layer is formed of a fluorescent material, a host may include BH232 (available from Idemitsu), and/or BH215 (available from Idemitsu), and a dopant may include BD142 (available from Idemitsu), and/or D052 (available from Idemitsu).

Also, the organic layer 120 may further include at least one of a hole transport layer, an electron injection layer, an electron transport layer and a hole blocking layer.

The hole transport layer may be formed of an arylene diamine derivative, a starburst compound, a biphenyl diamine derivative having a spiro group, and/or a trapezoid compound, and more particularly, may be formed of N,N-diphenyl-N,N-bis(4-methylphenyl)-1,1-biphenyl-4,4-diamine (TPD), and/or 4,4-bis[N-(1-naphthyl)-N-phenylamino]biphenyl (NPB).

The hole blocking layer serves to prevent or block transfer of a hole into the electron injection layer when hole mobility is higher than electron mobility in an organic emission layer. Here, the hole blocking layer may be formed of 2-biphenyl-4-yl-5-(4-t-butylphenyl)-1,3,4-oxydiazole (PBD), and/or spiro-PBD and TAZ.

The electron transport layer is formed of a metal compound which may easily hold an electron therein, and may be formed of Alq3 having an excellent characteristic capable of safely transporting an electron provided from the cathode electrode.

The electron injection layer may be formed of a 1,3,4-oxydiazole derivative, a 1,2,4-triazole derivative, and/or LiF.

Also, the organic layer 120 may be formed by vacuum deposition, ink-jet printing and/or laser induced thermal imaging (LITI).

A second electrode 130 is formed on the organic layer 120. The second electrode 130 may be formed of Ag, Al, Ca, Mg or an alloy thereof, which has a low work function.

In addition, in the top-emission OLED display device described above, the second electrode 130 may be formed of an MgAg alloy or an AlAg alloy.

Accordingly, the OLED display device according to the exemplary embodiments of the present invention can be formed (or completed) as described above.

The following examples illustrate the present invention in more detail. However, the present invention is not limited by these examples.

### EXAMPLE 1

### Mixed Host Example

An ITO layer was formed on a substrate to have a thickness of 70 Å. A hole injection layer was formed to a thickness of 750 Å on the ITO layer using IDE406 (available from Idemitsu), and a hole transport layer was formed to a thickness of 150 Å thereon using IDE320 (available from Idemitsu). A blue emission layer containing BH 232 (available from Idemitsu) as a host material and 5 wt % BD142 (available from Idemitsu) as a dopant material was formed on the hole transport layer to have a thickness of 80 Å. Also, a green emission layer containing a mixed host of 75% CBP (available from UDC) as a first host and 25% TMM (available from Covion) as a second host, and 7 wt % GGD01 (available from Gracel) as a dopant material was formed on the blue emission layer to have a thickness of 100 Å. A red emission layer containing a mixed host of 75% CBP (available from UDC) as a first host and 25% TMM (available from Covion) as a second host, and 12 wt % RD25 (available from UDC) as a dopant material was formed on the green emission layer to have a thickness of 120 Å. An electron transport layer was formed on the red emission layer to have a thickness of 250 Å using LG201 (available from LG). An electron injection layer was formed on the electron transport layer to have a thickness of 5 Å using LiF. A second electrode was formed on the electron injection layer to have a thickness of 2000 Å using Al.

### COMPARATIVE EXAMPLE 1

### Single Host Example

An ITO layer was formed on a substrate to have a thickness of 70 Å. A hole injection layer was formed to a thickness of 750 Å on the ITO layer using IDE406 (available from Idemitsu), and a hole transport layer was formed to a thickness of 150 Å thereon using IDE320 (available from Idemitsu). A blue emission layer containing BH 232 (available from Idemitsu) as a host material and 5 wt % BD142 (available from Idemitsu) as a dopant material was formed on the hole transport layer to have a thickness of 80 Å. Also, a green emission layer containing CBP (available from UDC) as a host material and 7 wt % GGD01 (available from Gracel) as a dopant material was formed on the blue emission layer to have a thickness of 100 Å. A red emission layer containing CBP (available from UDC) as a host material and 12 wt % RD25 as a dopant material was formed on the green emission layer to have a thickness of 120 Å. An electron transport layer was formed on the red emission layer to have a thickness of 250 Å using LG201 (available from LG). An electron injection layer was formed on the electron transport layer to have a thickness of 5 Å using LiF. A second electrode was formed on the electron injection layer to have a thickness of 2000 Å using Al.

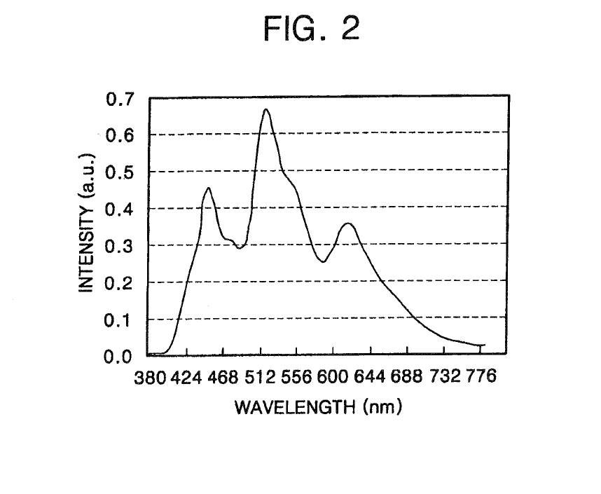

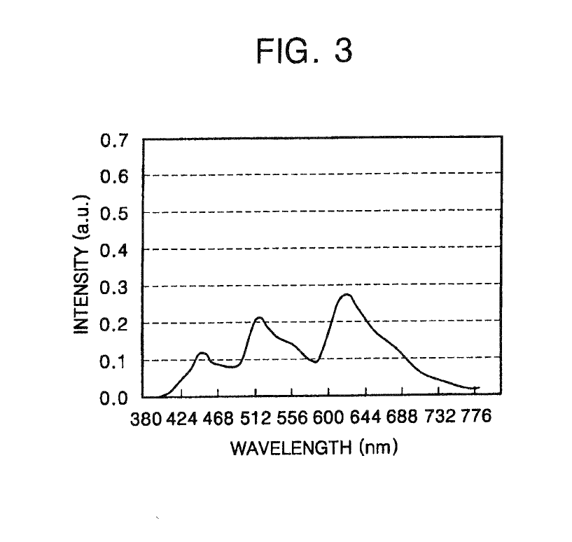

FIG. 2 is a graph illustrating an EL spectrum of Example 1, and FIG. 3 is a graph illustrating an EL spectrum of Comparative Example 1. The x axis denotes a wavelength (nm), and the y axis denotes intensity (a.u.: arbitrary unit).

Referring to FIG. 2, a blue peak is the highest at a wavelength of 424 to 468 nm, and has an intensity of about 0.45. A green peak is the highest at a wavelength of 512 nm, and has an intensity of about 0.65. Also, a red peak is the highest at a wavelength of 600 to 644 nm, and has an intensity of about 0.35.

Referring to FIG. 3, a blue peak is the highest at a wavelength of 424 to 468 nm, and has an intensity of about 0.1. A green peak is the highest at a wavelength of 512 nm, and has an intensity of about 0.2. Also, a red peak is the highest at a wavelength of 600 to 644 nm, and has an intensity of about 0.25.

As such, it can be noted that, in Example 1, the blue peak has a 4 times higher intensity, the green peak has a 3 times higher intensity and the red peak has a 1.5 times higher intensity than the corresponding red, green and blue peaks in Comparative Example 1.

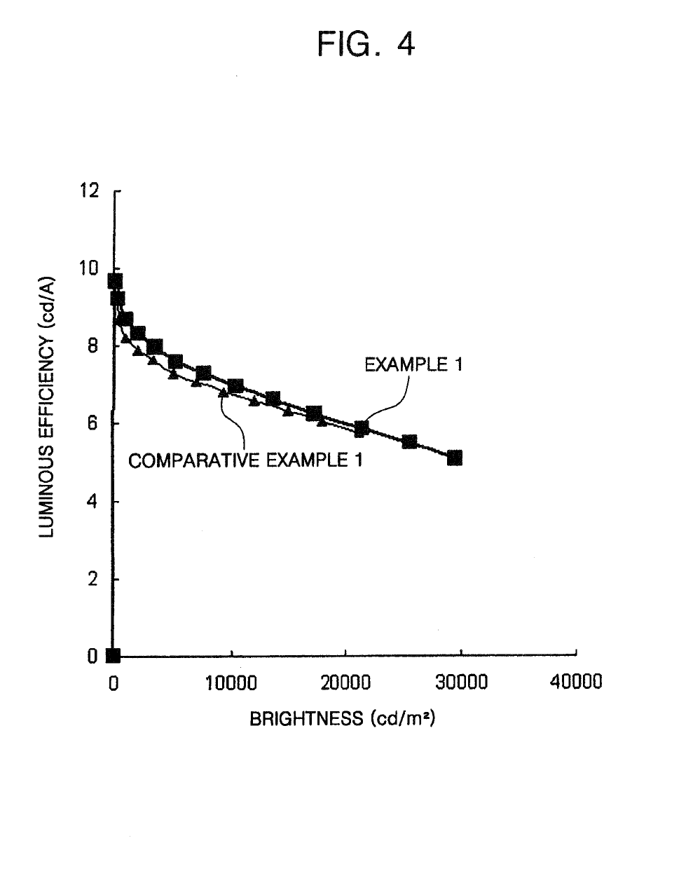

FIG. 4 is a graph illustrating the relationship between luminous efficiency and brightness of Example 1 and Comparative Example 1. The x axis denotes brightness (cd/m²) and the y axis denotes luminous efficiency (cd/m²).

Referring to FIG. 4, when brightness is 10,000 cd/m², luminous efficiency of Example 1 is about 7 cd/A, and that of Comparative Example 1 is about 6.6 cd/A. Also, when brightness is 20,000 cd/m2, luminous efficiency of Example 1 is about 5.9 cd/A, and that of Comparative Example 1 is about 5.8 cd/A.

Accordingly, it can be noted that Example 1 and Comparative Example 1 have a luminous efficiency of about 0.4 cd/A until the brightness goes to 10,000 cd/m² or higher.

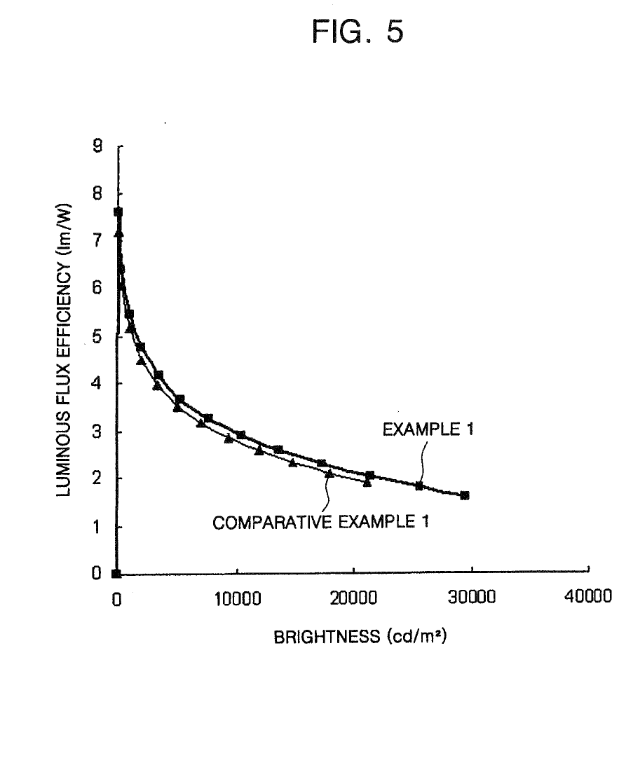

FIG. 5 is a graph illustrating the relationship between luminous flux efficiency and brightness in Example 1 and Comparative Example 1. The x axis denotes brightness (cd/m²), and the y axis denotes luminous flux efficiency (lm/W).

Referring to FIG. 5, when the brightness is 10,000 cd/m², the luminous flux efficiency of Example 1 is about 3.0 lm/W, and the luminous flux efficiency of Comparative Example 1 is about 2.7 lm/W. Also, when the brightness is 20,000 cd/m², the luminous flux efficiency of Example 1 is about 2.1 lm/W, and the luminous flux efficiency of Comparative Example 1 is about 2.0 lm/W.

Accordingly, it can be noted that Example 1 and Comparative Example 1 have a luminous flux efficiency of about 0.3 lm/W until the brightness goes to 10,000 cd/m² or higher.

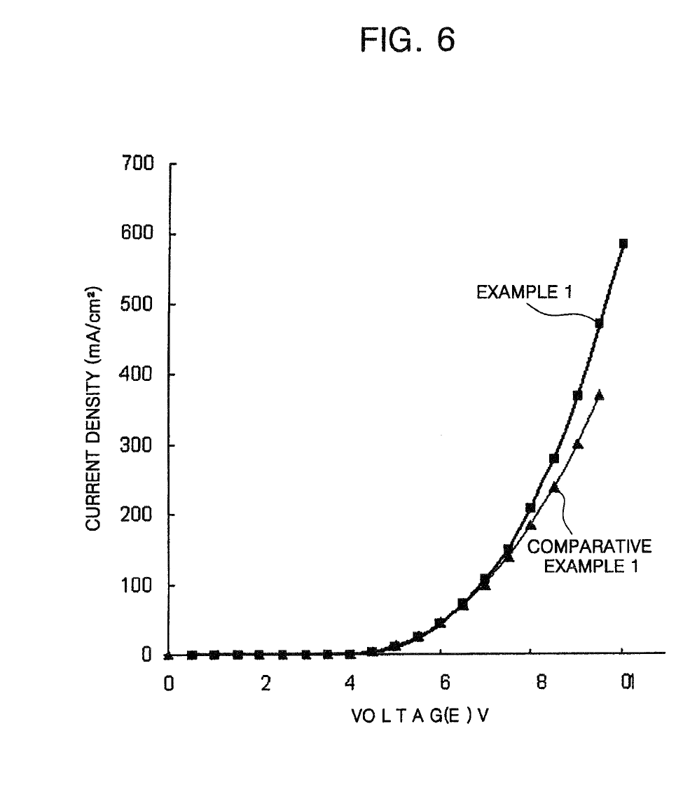

FIG. 6 is a graph illustrating the relationship between current density and driving voltage in Example 1 and Comparative Example 1. The x axes denote driving voltage (V), and the y axes denote current density (mA/cm²).

Referring to FIG. 6, there is almost no difference in the current density between Example 1 and Comparative Example 1 until the driving voltage goes to 6V. Also, when the driving voltage is 8V, the current density of Example 1 is about 206.6 mA/cm², and the current density of Comparative Example 1 is about 183.09 mA/cm². Also, when the driving voltage is 10V, the current density of Example 1 is about 583.5 mA/cm², and the current density of Comparative Example 1 is about 445.6 mA/cm².

Accordingly, it can be noted that when the driving voltage is more than 6V, the current density of Example 1 has a noticeable improvement over that of Comparative Example 1.

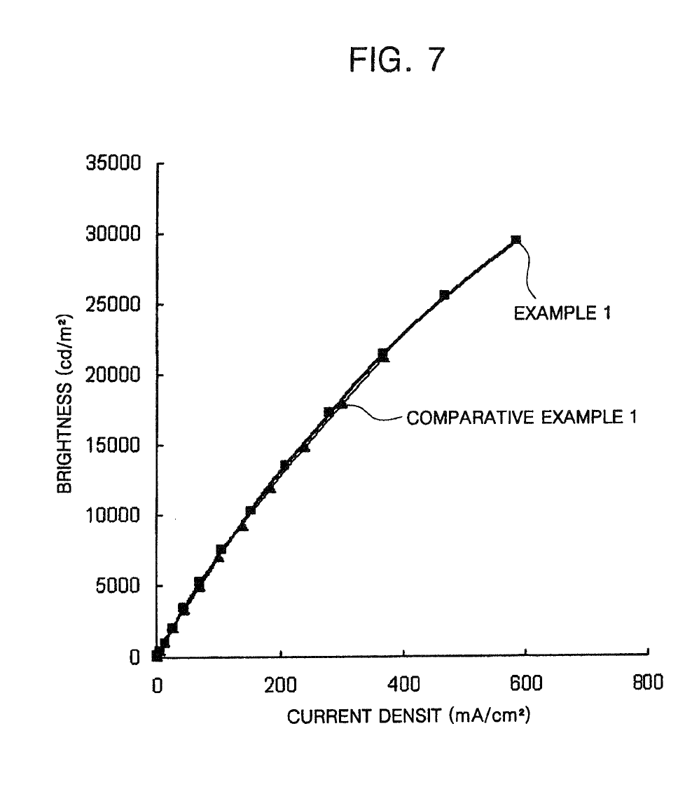

FIG. 7 is a graph illustrating the relationship between current density and brightness in Example 1 and Comparative Example 1. The x axis denotes current density (mA/cm²), and the y axis denotes brightness (cd/m²).

Referring to FIG. 7, when the current density is 200 mA/cm², the brightness of Example 1 is about 13,620 cd/m², and the brightness of Comparative Example 1 is about 13,000 cd/m². When the current density is 400 mA/cm², the brightness of Example 1 is about 23,000 cd/m², and the brightness of Comparative Example 1 is about 22,600 cd/m².

Accordingly, it can be noted that when the same current density is applied to Example 1 and Comparative Example 1, the brightness of Example 1 is higher than that of Comparative Example 1.

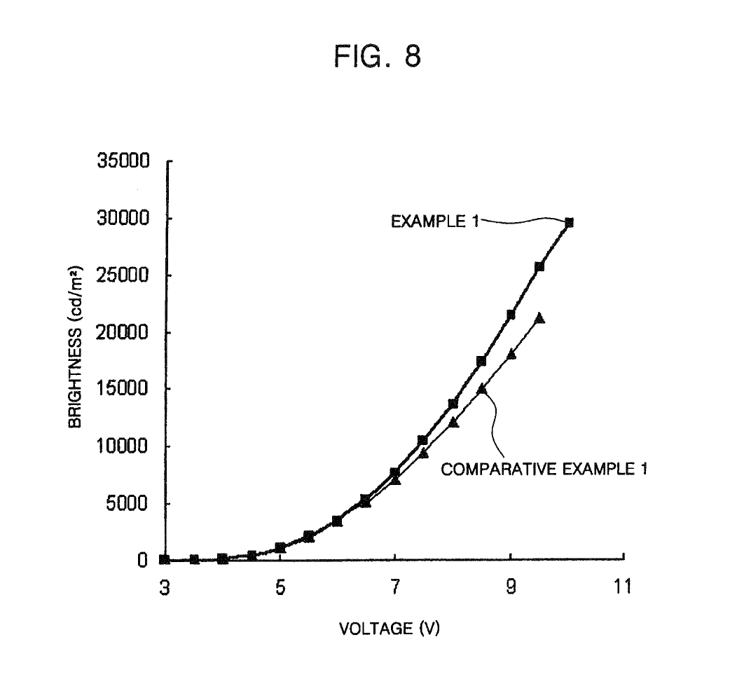

FIG. 8 is a graph illustrating the relationship between brightness and driving voltage in Example 1 and Comparative Example 1. The x axis denotes driving voltage (V), and the y axis denotes brightness (cd/m²).

Referring to FIG. 8, when the driving voltage is 7V, the brightness of Example 1 is about 7,611 cd/m², and the brightness of Comparative Example 1 is about 7,029 cd/m². Also, when the driving voltage is 8V, the brightness of Example 1 is about 13,620 cd/m², and the brightness of Comparative Example 1 is about 11,990 cd/m². Also, when the driving voltage is 9V, the brightness of Example 1 is about 21,400 cd/m², and the brightness of Comparative Example 1 is about 17,970 cd/m².

Accordingly, it can be noted that when the same driving voltage is applied to the device, the brightness of Example 1 is higher than that of Comparative Example 1.

In view of the foregoing, the present invention may provide an OLED display device with improved emission intensities of R, G and B peaks and increased life-span. Thus, reliability of the device may also be improved.

While the present invention has been described in connection with certain exemplary embodiments, it is to be understood that the invention is not limited to the disclosed embodiments, but, on the contrary, is intended to cover various modifications and equivalent arrangements included within the spirit and scope of the appended claims, and equivalents thereof.

What is claimed is:

1. An organic light emitting diode (OLED) display device, comprising:
a substrate;
a first electrode on the substrate;
an organic layer on the first electrode, and including a white emission layer comprising a mixed host including a first host and a second host having a different polarity from the first host; and
a second electrode on the organic layer.

2. The device according to claim 1, wherein the first host comprises a hole transport material, and the second host comprises an electron transport material.

3. The device according to claim 2, wherein the hole transport material comprises an aryl amine series compound and/or a starburst amine compound.

4. The device according to claim 2, wherein the electron transport material comprises at least one selected from the group consisting of a metal complex having a quinoline skeleton, a metal complex having a benzoquinoline skeleton, a mixed ligand complex, an oxazole ligand, and a thiazole ligand.

5. The device according to claim 1, wherein the mixed host comprises from about 50 to about 75% of the first host, and from about 25 to about 50% of the second host.

6. The device according to claim 1, wherein the white emission layer is a multi-layered layer.

7. The device according to claim 6, wherein the multi-layered layer is a double or triple layered layer.

8. The device according to claim 7, wherein the double layered layer comprises an orange-red emission layer and a blue emission layer.

9. The device according to claim 7, wherein the triple layered layer comprises a red emission layer, a green emission layer, and a blue emission layer.

10. A method of fabricating an organic light emitting diode (OLED) display device, the comprising:
preparing a substrate;
forming a first electrode on the substrate;
forming an organic layer including a white emission layer comprising a mixed host including a first host and a second host having a different polarity from the first host on the first electrode; and
forming a second electrode on the organic layer.

11. The method according to claim 10, wherein the forming of the organic layer comprises forming the first host to comprise a hole transport material, and forming the second host to comprise an electron transport material.

12. The method according to claim 11, wherein the hole transport material is formed to comprise an aryl amine series compound and/or a starburst amine compound.

13. The method according to claim 11, wherein the electron transport material is formed to comprise a metal complex having a quinoline skeleton, a metal complex having a benzoquinoline skeleton, a mixed ligand complex, an oxazole ligand, and/or a thiazole ligand.

14. The method according to claim 10, wherein the forming of the organic layer comprises forming the mixed host to comprise from about 50 to about 75% of the first host, and from about 25 to about 50% of the second host.

15. The method according to claim 10, wherein the forming the organic layer comprises forming the white emission layer as a multi-layered layer.

16. The method according to claim 15, wherein the multi-layered layer is formed as a double or triple layered layer.

17. The method according to claim 16, wherein the double layered layer is formed to comprise an orange-red emission layer and a blue emission layer.

18. The method according to claim 16, wherein the triple layered layer is formed to comprise a red emission layer, a green emission layer, and a blue emission layer.
